(19) United States
(12) Patent Application Publication
(10) Pub. No.: US 2015/0095726 A1
(43) Pub. Date: Apr. 2, 2015

(54) SNR margin determination based on FEC code and/or ECC decoding statistics

(71) Applicant: BROADCOM CORPORATION, IRVINE, CA (US)

(72) Inventors: Kelly Brian Cameron, Irvine, CA (US); Hau Thien Tran, Irvine, CA (US); Tak Kwan Lee, Irvine, CA (US); Ba-Zhong Shen, Irvine, CA (US); Bruce Joseph Currivan, Los Altos, CA (US)

(73) Assignee: BROADCOM CORPORATION, IRVINE, CA (US)

(21) Appl. No.: 14/499,934

(22) Filed: Sep. 29, 2014

Related U.S. Application Data
(60) Provisional application No. 61/884,116, filed on Sep. 29, 2013.

(51) Int. Cl. G06F 11/07; H03M 13/11; H04L 1/00; G06F 11/10

(52) U.S. Cl. CPC G06F 11/076; G06F 11/10; H03M 13/1102; H04L 1/0058
USPC 714/704

(57) ABSTRACT

A communication device operates to support communications with one or more other communication devices. The communication device includes a processor and a communication interface to perform various operations including receiving forward error correction (FEC) coded signals from another communication device. The communication device iteratively decodes the FEC coded signals to make estimates of information encoded therein. The communication device then determines an operational error check rate based on error check failure of at least one of the FEC coded signals after performing a predetermined number of decoding iterations (e.g., that is less than a maximum number of decoding iterations performed by the device). The device then determines a signal to noise ratio (SNR) margin of the communication device by applying the operational error check rate to a characterization of the communication device that relates error check rate and SNR.

### CROSS REFERENCE TO RELATED PATENTS/PATENT APPLICATIONS

### Provisional Priority Claim

The present U.S. Utility patent application claims priority pursuant to 35 U.S.C. §119(e) to U.S. Prov. Patent App. No. 61/884,116, entitled “Signal to noise ratio (SNR) margin determination based on low density parity check (LDPC) decoding statistics,” filed Aug. 29, 2013, which is hereby incorporated herein by reference in its entirety and made part of the present U.S. Utility patent application for all purposes.

### BACKGROUND

1. Technical Field

The present disclosure relates generally to communication systems; and, more particularly, to determining signal to noise ratio (SNR) and/or SNR margin of communications within such communication systems.

2. Description of Related Art

Data communication systems have been under continual development for many years. The primary goal within such communication systems is to transmit information successfully between devices. Unfortunately, many things can deleteriously affect signals transmitted within such systems resulting in degradation of or even complete failure of communication. Examples of adverse effects include interference and noise that may be caused by various sources including other communications, low-quality links, degraded or corrupted interfaces and connectors, etc.

Some communication systems use forward error correction (FEC) coding and/or error correction code (ECC) coding to increase the reliability and the amount of information that may be transmitted between devices. When a signal incurs one or more errors during transmission, a receiver device can employ the FEC or ECC coding to try to correct those one or more errors.

A continual and primary directive in this area of development has been to try continually to lower the signal to noise ratio (SNR) required to achieve a given bit error ratio (BER) or symbol error ratio (SER) within a communication system. The Shannon limit is the theoretical bound for channel capacity for a given modulation and code rate. The ideal goal has been to try to reach Shannon's channel capacity limit in a communication channel. Shannon's limit may be viewed as being the data rate per unit of bandwidth (i.e., spectral efficiency) to be used in a communication channel, having a particular SNR, where transmission through the communication channel with arbitrarily low BER or SER is achievable.

In some instances, it is desirable to determine the SNR of a signal when transmitted from a first communication device compared to the SNR of that same signal when received at a second communication device. In other instances, it may be desirable to determine the SNR of a signal received at a communication device in comparison to a lowest SNR at which acceptable performance is achieved. Generally, this can be referred to as SNR margin. Prior art approaches to determine SNR margin can be complex, computationally costly, and inefficient. Prior art approaches to determine SNR margin are performed in the front end of the device (e.g., analog front end (AFE), demodulator, etc.). As such, such prior art approaches can be highly inaccurate based on inaccurate SNR measurements. There continues to exist a great deal of room for improvement in determining SNR margin within communication systems.

### BRIEF DESCRIPTION OF THE SEVERAL VIEWS OF THE DRAWINGS

FIG. 1A is a diagram illustrating an embodiment of one or more communication systems.

FIG. 1B is a diagram illustrating another embodiment of one or more communication systems.

FIG. 2A is a diagram illustrating a communication device (CD) operative within one or more communication systems.

FIG. 2B is a diagram illustrating a communication device (CD) operative within one or more communication systems.

FIG. 2C is a diagram illustrating an example of a characterization of a communication device for use to determine signal to noise ratio (SNR) margin of a communication device based on error check failure after performing a predetermined number of decoding iterations.

FIG. 3A is a diagram illustrating an example of a characterization of a communication device for use to determine SNR margin of a communication device based on an average number of decoding iterations.

FIG. 3B is a diagram illustrating an example of a characterization of a communication device for use to determine SNR margin of a communication device based on bit error rate (BER) and/or block error rate (BLER) and decoder corrected bit rate.

FIG. 4A is a diagram illustrating an example of operations for determining SNR margin of a communication device based on decoder corrected bit rate.

FIG. 4B is a diagram illustrating an example of operations for determining SNR margin of a communication device based on error check failure after performing a predetermined number of decoding iterations.

FIG. 5A illustrates an example of an LDPC (Low Density Parity Check) code bipartite graph.

FIG. 5B illustrates an example of decoding of an LDPC coded signal.

FIG. 5C illustrates an example of an LDPC matrix that is partitioned into sub-matrices.

FIG. 6A is a diagram illustrating an example of an LDPC matrix partitioned into a left hand side matrix and a right hand side matrix.

FIG. 6B is a diagram illustrating examples of right hand side matrices of LDPC matrices.

FIG. 7A is a diagram illustrating an example of operations for determining SNR margin of a communication device based on LDPC decoder corrected bit rate.

FIG. 7B is a diagram illustrating an example of operations for determining SNR margin of a communication device based on LDPC syndrome error failure after performing a predetermined number of decoding iterations.

FIG. 8A is a diagram illustrating an example of a communication device that receives first at least one signal from another communication device at a first time.

FIG. 8B is a diagram illustrating an example of the communication device of FIG. 8A that transmits SNR margin to the other communication device at a second time.

FIG. 8C is a diagram illustrating an example of a communication device that receives second at least one signal from another communication device at a third time.

FIG. 8D is a diagram illustrating an example of various operational parameters for use in generating and transmitting signals based on SNR margin and changes thereof.

FIG. 9A is a diagram illustrating an embodiment of a method for execution by one or more communication devices.

FIG. 9B is a diagram illustrating another embodiment of a method for execution by one or more communication devices.

### DETAILED DESCRIPTION

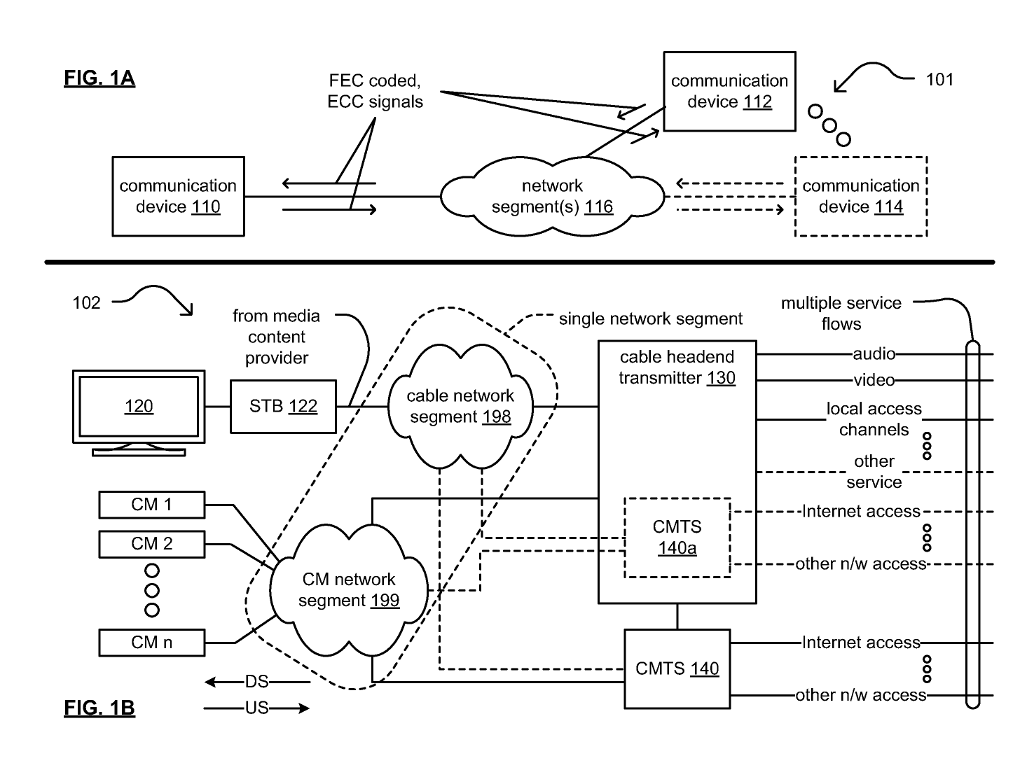

FIG. 1A is a diagram illustrating an embodiment 101 of one or more communication systems. One or more network segments 116 provide communication inter-connectivity for at least two communication devices 110 and 112 (also referred to as CDs in certain locations in the diagrams). Note that general reference to a communication device may be made generally herein using the term ‘device’ (e.g., device 110 or CD 110 when referring to communication device 110, or devices 110 and 112, or CDs 110 and 112, when referring to communication devices 110 and 112). Generally speaking, any desired number of communication devices are included within one or more communication systems (e.g., as shown by communication device 114).

The various communication links within the one or more network segments 116 may be implemented using any of a variety of communication media including communication links implemented as wireless, wired, optical, satellite, microwave, and/or any combination thereof, etc. communication links. Also, in some instances, communication links of different types may cooperatively form a connection pathway between any two communication devices. Considering one possible example, a communication pathway between devices 110 and 112 may include some segments of wired communication links and other segments of optical communication links. Note also that the devices 110-114 may be of a variety of types of devices including stationary devices, mobile devices, portable devices, etc. and may support communications for any of a number of services or service flows including data, telephony, television, Internet, media, synchronization, etc.

In an example of operation, device 110 includes a communication interface to support communications with one or more of the other devices 112-114. This communication may be bidirectional/to and from the one or more of the other devices 112-114 or unidirectional (or primarily unidirectional) from the one or more of the other devices 112-114.

In an example, device 110 includes a communication interface and a processor to perform functions including receiving and transmitting of signals, encoding and decoding of signals, determining SNR margin based on processing of one or more signals, etc. From certain perspectives, the processor performs operations including directing the function of the communication interface for transmitting and receiving signals. The communication interface may be implemented to perform a variety of functions including digital to analog conversion, analog-to-digital conversion, frequency conversion (up or down), scaling, filtering, etc. and/or any other functions to generate signals suitable for transmission via one or more communication channels and/or front-end processing of signals received via the one or more communication channels for other channels. Generally speaking, analog front end (AFE) related operations are performed within the communication interface.

The device 110 operates to receive forward error correction (FEC) code and/or error correction code (ECC) coded signals (e.g., generally referred to as signals) from another device, such as device 112. The device 110 then performs decoding of those signals to make estimates of information encoded therein. When performing an iterative decoding process on those signals, the device 110 determines an operational error check rate based on error check failure of at least one of the signals after performing a predetermined number of decoding iterations. For example, considering a situation where a first number of decoding iterations successfully decode the signals (e.g., e.g., N1=15 decoding iterations), the device 110 determines an operational error check rate based on error check failure of any of the signals after performing less than that first number of decoding iterations, N1 (e.g., a maximum number of decoding iterations). In one instance, the operational error check rate is based on error check failure after performing only a second number, N2, decoding iterations, where N2 is a positive integer that is less than N1 (e.g., N1=15 and N2=8). The device 110 then determines a signal to noise ratio (SNR) margin of the device by applying the determined operational error check rate to the characterization of the device that relates error check rate and SNR. For example, information that characterizes the device 110 may be known beforehand. By determining the operational error check rate based on error check failure as determined during decoding of at least one of the received signals at an iteration count less than the number of decoding iterations needed to successfully decode the signals, the current operating SNR of the device 110 may be determined. The SNR margin is then the difference between the SNR of the device 110 and is determined based on the operational error check rate and the targeted operating SNR (e.g., at a performance of SNR=30 dB).

In an example, consider that 2 of the 1000 received signals fails to decode properly after performing N2=8 decoding iterations, and where N1=15 decoding iterations results in successful decoding of all 1000 received signals. This would then provide an error check failure total of 2 and a corresponding operational error check rate of 2×10⁻³ or 0.002 (e.g., the error check failure total, 2, divided by the total number of received signals, 1000). This operational error check rate (e.g., the error check failure total relative to the number of received signals or the error check failure total divided by the number of received signals) is then applied to a characterization of the device 110 that relates error check rate and SNR. This will result in determining the SNR of the device 110. The SNR margin is then the difference between this determined SNR of the device 110 and a lowest SNR associated with a targeted performance. Considering some possible values, if the determined SNR of the device 110 is 35 dB, and the lowest SNR associated with a targeted performance is 30 dB, then the SNR margin would be 5 dB. Alternatively, if the determined SNR of the device 110 is 34 dB, and assuming the same lowest SNR associated with the targeted performance, then the SNR margin would be 4 dB.

Note that SNR margin of the device may be determined using FEC code and/or ECC decoding statistics based on the operations that are performed during decoding of coded signals. With very little additional complexity, appropriate tracking of certain information during the decoding processing allows the device 110 to determine its SNR and its SNR margin.

Also, note that prior art approaches may try to determine SNR margin based on the front end of a device (e.g., based on statistics related to the analog front end (AFE), the demodulator, etc.). As such, those SNR margin calculations and determinations may be relatively inaccurate. For example, this inaccuracy may be attributed, at least in part, to the fact that such approaches may not deal directly with BER or BLER. As a consequence, decisions made to adapt operation based on SNR margin determination performed using prior techniques may be made in error. As an example, if the accuracy of that SNR margin calculation using a prior art technique is ±3 dB, then adjustment of any operational parameters will take into account this possible inaccuracy. As such, it is likely that operational decisions be made to ensure that an adequate SNR margin will remain.

In contrast, a device implemented as described herein uses statistics generated during the decoding processing itself to determine SNR margin. In other words, by using the FEC code and/or ECC decoding statistics themselves, the device 110 can generate a very highly accurate estimate of SNR and SNR margin of the device 110. As such, adjustment of one or more operational parameters of the device 110 and/or another device (e.g., device 112) in communication with the device 110 can be made with a firm confidence on the determined SNR margin. Such adjustment can then be made so that subsequent operation may be made with a relatively small SNR margin. Alternatively, when a relatively large SNR margin is determined, and with such accurate knowledge related to the determined relatively large SNR margin, when an adequate SNR margin is available, the operational parameters may be adjusted to capitalize on that SNR margin.

Different adaptation of one or more operational parameters may be performed based on information related to SNR margin. In one example, when operation is performed with a relatively large SNR margin, then power may be adjusted to reduce that SNR margin. In one possible implementation, a receiver device, which calculates the SNR margin, transmits information related to the SNR margin to a transmitter device. When there is a sufficiently large SNR margin, the transmitter device may reduce transmit power for use in subsequent communications. In an alternative implementation, the transmitter device may maintain the same transmit power yet increase the modulation used for subsequent communications (e.g., increase the number of constellation points used in one or more of the symbols to be transmitted). Any of a number of different operational parameters may be adjusted based on SNR margin for a transmitter and/or receiver device that in communication with one another via one or more communication links.

Generally, within a communication system and/or communication device, the operating signal to noise ratio (SNR) margin may be defined as a function of the current operating SNR and the targeted operating SNR as follows: SNR margin=current operating SNR−targeted operating SNR

If the communication device and/or system has information indicating that it has a certain operating SNR margin, it can adapt its operation accordingly. For example, the communication system and/or one or more communication devices may change the modulation order (e.g., from a relatively lower order modulation to a relatively higher order modulation, such as from 16 quadrature amplitude modulation (QAM) to 256 QAM) to change (increase) the system data throughput).

Note that, when the SNR margin is less or diminishing, the communication system and/or one or more of the communication devices may change the modulation order from a relatively higher order modulation to a relatively lower order modulation, such as from 16 quadrature amplitude modulation (QAM) to quadrature phase shift keying (QPSK) of 4-QAM to change (reduce) the system data throughput. Also, the communication system and/or one or more of the communication devices may change (e.g., reduce) transmit power to save power. For another example, the communication system and/or one or more of the communication devices may change the transmit power used for communications.

Note also that any of a number of different types of FEC code and/or ECC may be used. Depending on the particular code that is used, different characteristics related to that code may be used to determine the operational error check rate (e.g., the error check failure total relative to a number of coded signals). In an example of operation, device 110 performs encoding of one or more bits to generate one or more coded bits used to generate the modulation data (or generally, data) using any desired one or more FEC codes and/or ECCs to generate one or more coded bits. Examples of FEC code and/or ECC may include turbo code, convolutional code, turbo trellis coded modulation (TTCM), low density parity check (LDPC) code, Reed-Solomon (RS) code, BCH (Bose and Ray-Chaudhuri, and Hocquenghem) code, etc. The one or more coded bits may then undergo modulation or symbol mapping to generate modulation symbols. The modulation symbols may include data intended for one or more recipient devices. Note that such modulation symbols may be generated using any of various types of modulation coding techniques. Examples of such modulation coding techniques may include binary phase shift keying (BPSK), quadrature phase shift keying (QPSK), 8-phase shift keying (PSK), 16 quadrature amplitude modulation (QAM), 32 amplitude and phase shift keying (APSK), etc., uncoded modulation, and/or any other desired types of modulation including higher ordered modulations that may include even greater number of constellation points (e.g., 1024 QAM, etc.) in single-carrier (SC) systems or multiple-carrier systems (e.g., orthogonal frequency division multiplexing (OFDM), orthogonal frequency division multiple access (OFDMA), etc.).

Also, in conjunction with or in other examples, device 110 may use other types of decoding statistics to determine SNR margin. In one implementation, device 110 uses an average number of decoding iterations across a number of decoded signals to determine the SNR margin. In another implementation, device 110 uses an FEC code and/or ECC corrected bit rate to determine the SNR margin. In another implementation, device 110 uses a determined operational error check rate (e.g., the error check failure total relative to a number of coded signals such that the error check failure total) is determined based on a number of decoding iterations that is fewer than a maximum number of decoding iterations. Device 110 may be implemented to use any one or more of these various approaches to determine SNR margin. Once the SNR margin is known, device 110 may adjust any one or more of its own operational parameters and/or communicate information to another device, such as device 112, so that the other device may adjust any one or more of its operational parameters.

FIG. 1B is a diagram illustrating another embodiment 102 of one or more communication systems. A cable headend transmitter 130 provides service to a set-top box (STB) 122 via cable network segment 198. The STB 122 provides output to a display capable device 120. The cable headend transmitter 130 can support any of a number of service flows such as audio, video, local access channels, as well as any other service of cable systems. For example, the cable headend transmitter 130 can provide media (e.g., video and/or audio) to the display capable device.

The cable headend transmitter 130 may provide operation of a cable modem termination system (CMTS) 140a. For example, the cable headend transmitter 130 may perform such CMTS functionality, or a CMTS may be implemented separately from the cable headend transmitter 130 (e.g., as shown by reference numeral 140). The CMTS 140 can provide network service (e.g., Internet, other network access, etc.) to any number of cable modems (shown as CM 1, CM 2, and up to CM n) via a cable modem (CM) network segment 199. The cable network segment 198 and the CM network segment 199 may be part of a common network or common networks. The cable modem network segment 199 couples the cable modems 1-n to the CMTS (shown as 140 or 140a). Such a cable system (e.g., cable network segment 198 and/or CM network segment 199) may generally be referred to as a cable plant and may be implemented, at least in part, as a hybrid fiber-coaxial (HFC) network (e.g., including various wired and/or optical fiber communication segments, light sources, light or photo detection complements, etc.).

A CMTS 140 (or 140a) is a component that exchanges digital signals with cable modems 1-n on the cable modem network segment 199. Each of the cable modems is coupled to the cable modem network segment 199, and a number of elements may be included within the cable modem network segment 199. For example, routers, splitters, couplers, relays, and amplifiers may be contained within the cable modem network segment 199. Generally speaking, downstream information flows from the CMTS 140 to the connected cable modems (e.g., CM 1, CM2, etc.), and upstream information flows from the cable modems to the CMTS 140.

Any of the various devices within this diagram may be implemented to include a processor and communication interface to generate and transmit signals to any one of the other devices and to receive and interpret signals from any one of the other devices. Considering one of the cable modems as an example, CM 1 may be implemented to include a processor and a communication interface. The processor receives, via the communication interface, FEC coded signals from CMTS 140. The processor then iteratively decodes the FEC coded signals to make estimates of information encoded therein. The processor also determines an error check failure total based on error check failure of at least one of the FEC coded signals after performing a predetermined number of decoding iterations. For example, considering an embodiment in which a maximum of 10 decoding iterations is performed, then the processor may determine the error check failure total based on error check failure of those of the FEC coded signals that are not successfully decoded after performing 5 decoding iterations (e.g., where a maximum number of decoding iterations is N1=10, and the less than maximum number of decoding iterations used to determine the error check failure total is N2=5). The processor then applies the error check failure total relative to the number of coded signals to determine an operational error check rate (e.g., the error check failure total divided by the number of coded signals). The processor then applies the operational error check rate to a characterization of the CM 1 that relate error check rate in SNR to determine the SNR margin of the CM 1. Then, the CM 1 may adjust any one or more of its operational parameters based on knowledge of the SNR margin. Alternatively, or in conjunction with, the CM 1 may communicate information of the SNR margin to the CMTS 140 so that the CMTS 140 may adjust any one or more of its operational parameters based on the knowledge of the SNR margin.

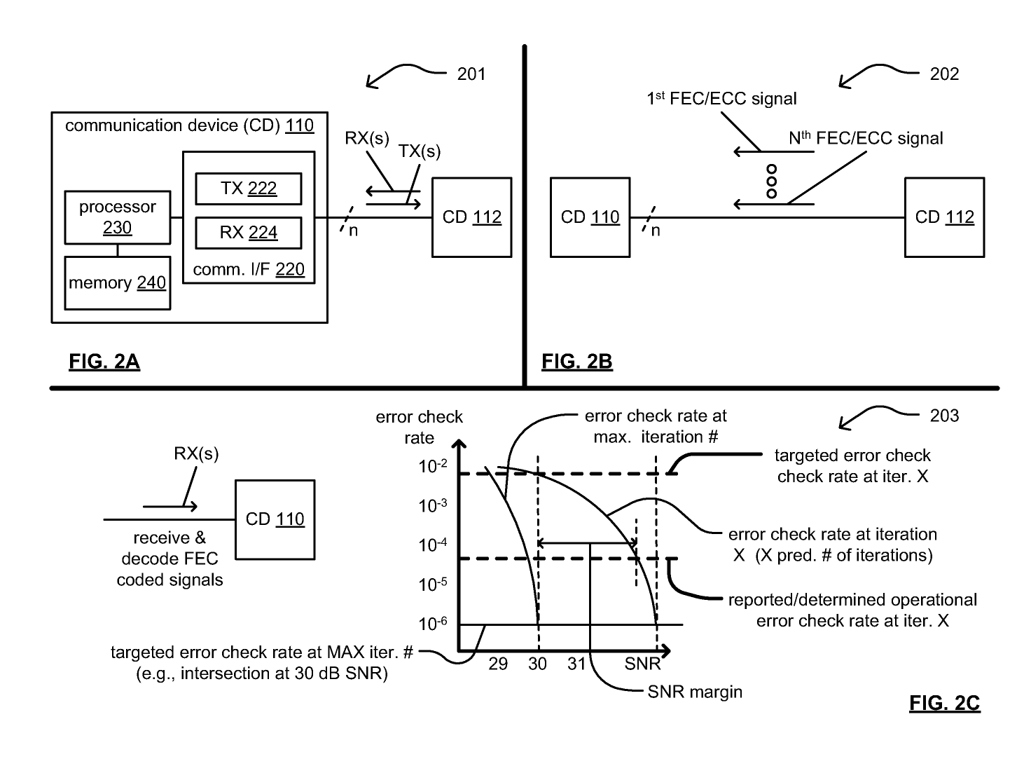

FIG. 2A is a diagram 201 illustrating a communication device (CD) 110 operative within one or more communication systems. The device 110 includes a communication interface 220 and a processor 230. The communication interface 220 includes functionality of a transmitter 222 and a receiver 224 to support communications with one or more other devices within a communication system. The device 110 may also include memory 240 to store information including one or more signals generated by the device 110 or such information received from other devices (e.g., device 112) via one or more communication channels. Memory 240 may also include and store various operational instructions for use by the processor 230 in regards to the processing of messages and/or other received signals and generation of other messages and/or other signals including those described herein. Memory 240 may also store information including one or more types of encoding, one or more types of symbol mapping, concatenation of various modulation coding schemes, etc. as may be generated by the device 110 or such information received from other devices via one or more communication channels. The communication interface 220 supports communications to and from one or more other devices (e.g., CD 112 and/or other communication devices). Operation of the communication interface 220 may be directed by the processor 230 such that processor 230 transmits and receives signals (TX(s) and RX(s)) via the communication interface 220.

In an example of operation, device 110's processor 230 receives, via the communication interface 220, a plurality of forward error correction (FEC) coded signals from device 112. The processor 230 then iteratively decodes the plurality of FEC coded signals to make estimates of information encoded therein. The processor 230 then determines an error check failure total based on error check failure of at least one of the plurality of FEC coded signals after performing a predetermined number of decoding iterations. The processor 230 then applies the error check failure total relative to the number of coded signals to determine an operational error check rate (e.g., the error check failure total divided by the number of coded signals). For example, if a maximum number of decoding iterations is N1, then the processor 230 determines how many of the signals do not pass error check failure after performing the predetermined number of decoding iterations, N2, which is less than N1. The processor 230 then applies this operational error check rate to a characterization of the communication device that relates error check rate and SNR.

Note that device 110 may be implemented to operate as any one or more of a satellite communication device, a wireless communication device, a wired communication device, a fiber-optic communication device, or a mobile communication device and implemented and/or operative within any one or more communication systems including a satellite communication system, a wireless communication system, a wired communication system, a fiber-optic communication system, or a mobile communication system.

FIG. 2B is a diagram 202 illustrating a communication device (CD) 110 operative within one or more communication systems. Device 110 supports communications to and from one or more other devices, such as device 112. In an example of operation, device 110 receives a number of signals (e.g., shown as 1^{st} FEC/ECC signal through N^{th} FEC/ECC signal) from device 112. In some instances, the device 110 receives a first number of signals during a first time, the device 110 receives a second number of signals during a second time, etc.

The device 110 may be configured to determine different SNR margins at different times based on decoding statistics associated with different groups of signals. If desired, decoding statistics associated with different numbers of signals may be used at different times and over different time periods to determine SNR margin. For example, in a relatively static or predictable communication system (e.g., a wire based, cable based, etc. communication system), decoding statistics associated with a relatively large number of signals may be used. Alternatively, in a more dynamic and changing communication system (e.g., a wireless, cellular, etc. communication system), decoding statistics associated with a relatively small number of signals may be used at a time. Also, note that decoding statistics associated with a first number of signals may be used to determine a first SNR margin and decoding statistics associated with a second number of signals may be used to determine a second SNR margin.

FIG. 2C is a diagram illustrating an example of a characterization of a communication device for use to determine signal to noise ratio (SNR) margin of a communication device based on error check failure after performing a predetermined number of decoding iterations. In an example, consider that device 110 receives and processes 10,000 blocks. The device 110 performs a maximum of N1=16 decoding iterations and an error check failure total is determined based on those of the 10,000 blocks that do not successfully decode after performing N2=8 decoding iterations. Consider a situation in which only one of the 10,000 blocks does not successfully decode after performing N2=8 decoding iterations (e.g., a predetermined number of decoding iterations that is less than the maximum number of decoding iterations). This would then provide an error check failure total of 1 and a corresponding operational error check rate of 1×10⁻⁴ or 0.0001 (e.g., the error check failure total, 1, divided by the total number of received blocks, 10,000).

The device 110 includes or has access to information that characterizes the device 110 and relates error check rate and SNR. This characterization may be performed and/or provided ‘a priori’, namely, before the device 110 is deployed and implemented within a communication system. Note also that different devices may perform different decoding operations and have different characterizations. If desired, the characterization of the device may be mapped to a standardized curve agreed upon among a number of device manufacturers. This way, different devices can associate their specific characterization to a standardized curve. Such comparison and application would then be made relative to such a standardized curve.

In such an instance, this error check failure total relative to the number of received signals provides the operational error check rate. Then, the operational error check rate is applied to a standardized curve that represents a characterization of the device 110 that relates error check rate and SNR. This will result in determining the current operating SNR of the device 110. The SNR margin is then the difference between this determined SNR of the device 110 and the targeted operating SNR. Considering some possible values, if the determined SNR of the device 110 is 33.2 dB, and the targeted operating SNR is 30 dB, then the SNR margin would be 3.2 dB. Alternatively, if the determined SNR of the device 110 is 31 dB, and assuming the same targeted operating SNR, then the SNR margin would be 1 dB.

Note also device 110 may be implemented to use different numbers of maximum decoding iterations and predetermined number of fewer than maximum number of decoding iterations may be used. For example, during a first period of time or when processing a first group of signals, device 110 performs a first maximum of N1=16 decoding iterations and N2=8 decoding iterations (e.g., a first predetermined number of decoding iterations that is less than the first maximum number of decoding iterations). Then, during a second period of time or when processing a second group of signals, device 110 performs a second maximum of N1=10 decoding iterations and N2=5 decoding iterations (e.g., a second predetermined number of decoding iterations that is less than the second maximum number of decoding iterations). Device 110 may be configured to adapt and change these various parameters over time.

In an alternative example, device 110 operates to generate statistics based on different sets of such parameters. Device 110 generates decoding statistics based on both decoding processing operations that use the first maximum of N1=16 decoding iterations and the first predetermined number N2=8 of decoding iterations as well as the second maximum of N1=10 decoding iterations and the second predetermined number N2=5 of decoding iterations when processing the same signals. Concurrent/parallel or serial processing operations may be performed to generate such decoding statistics. Decoding statistics generated based on different parameters may be more desirable in different applications.

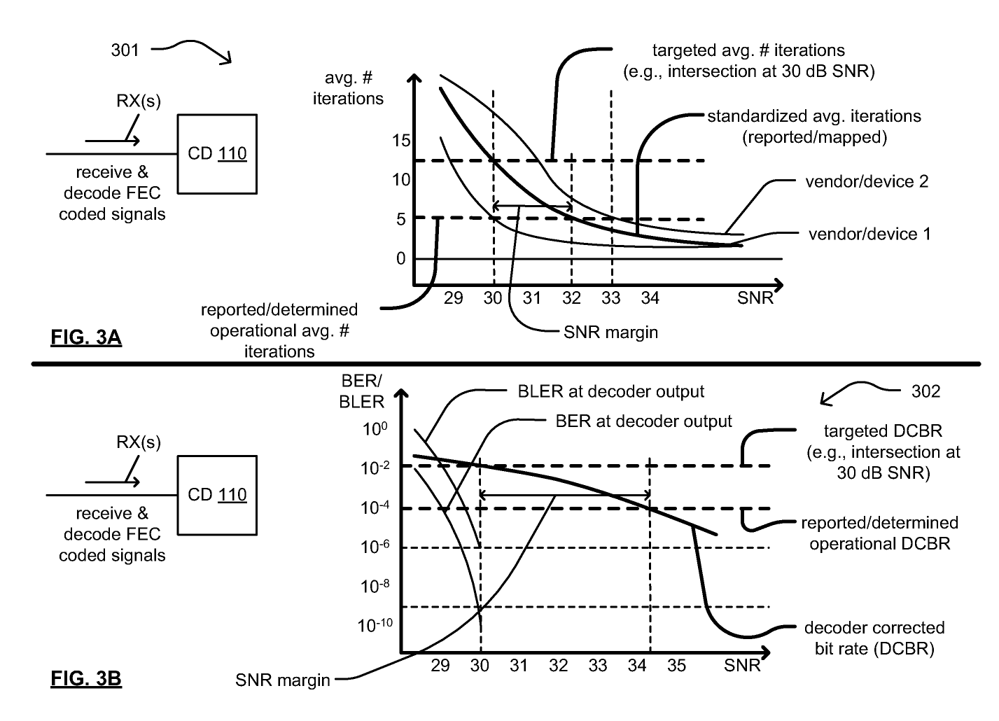

FIG. 3A is a diagram illustrating an example 301 of a characterization of a communication device for use to determine SNR margin of a communication device based on an average number of decoding iterations. The device 110 tracks the total number of decoding iterations required to decode each of the signals and determines the average number of decoding iterations required to perform any one signal. The device 110 then applies that determined average number of decoding iterations to a characterization of the device 110 that relates average number of decoding iterations SNR. The device 110 can then determine an estimate of the SNR margin based on this information.

With respect to this approach to determine SNR margin and considering a specific example that uses low density parity check (LDPC) coding, note that different LDPC decoders will report different number of average iterations based on the type of decoding approach being employed (e.g., layer decoding vs. flooding decoding vs. other decoding approaches to decode LDPC coded signals). Also, different devices may use different maximum number of iterations for LDPC decoding (e.g., a given chipset or communication device may be implemented to perform only a given maximum number of iterations for LDPC decoding, while another chipset or communication device may use another maximum number of iterations for LDPC decoding), thus the average number of iterations may also vary. Also, note that the average number of iterations may level off at higher SNR.

In one embodiment, chipsets or communication devices may be implemented to map their average number of iterations to the standardized curve of the average number of iterations (e.g., such as using floating-point flooding decoding with 15 maximum number of iterations as shown in FIG. 3A). However, note that there may be a granularity issue at higher SNR making it difficult to determine the actual SNR based on a relatively lower number of average decoding iterations given that the curves generally will flatten out to the right as SNR increases.

In an example, consider that the device 110 determines an average of approximately 5 decoding iterations is performed when decoding the particular number of signals, e.g. 1000 signals. The device 110 then determines an SNR of 32 dB based on the standardized average iterations curve, and consider a lowest possible SNR of 30 dB, then the SNR margin would be to 2 dB.

FIG. 3B is a diagram illustrating an example 302 of a characterization of a communication device for use to determine SNR margin of a communication device based on bit error rate (BER) and/or block error rate (BLER) and decoder corrected bit rate. In this diagram, the device 110 receives and decodes signals and also determines a decoder corrected bit rate based on decoding statistics associated with decoding those signals and applies the determined decoder corrected bit rate to a characterization of device 110 that relates bit error rate (BER) and/or block error rate (BLER) and decoder corrected bit rate (DCBR).

In an example, consider that the device 110 determines a DCBR of 1×10⁻⁴, then based on a characterization of the device 110, the device 110 determines an SNR of approximately 34.3 dB. Considering a targeted operating SNR of 30 dB, then the device 110 determines an SNR margin of approximately 4.3 dB.

Consider an example using LDPC coding and determining an LDPC-corrected-bit rate (LCBR). As can be seen the diagram, note that the LDPC-corrected-bit rate (LCBR) has better slope at higher SNR than the average number of iterations in the method described above with respect to FIG. 3A (e.g., using the average number of iterations to determine the signal to noise ratio (SNR) margin). This approach based on LCBR may be used in conjunction with the block error rate to know for certain that the system has SNR margin (e.g., when BER or BLER=0 or smaller than the targeted block error rate).

Note that some instances may have one LCBR on the whole codeword and/or multiple codewords and/or multiple LCBR's for multiple groups of bits in a codeword. This allows the system to know the SNR margin in different subcarriers and perform bit loading at the tone or subcarrier level (e.g., such as based on orthogonal frequency division multiplexing (OFDM)).

Note also that the LDPC-corrected-bit rate is identical to the channel BER (pre-LDPC-decoding BER) when LDPC decodes successfully. Therefore, this LCBR method does not have any potential issue with different LDPC decoders (e.g., layer decoding or flooding decoding).

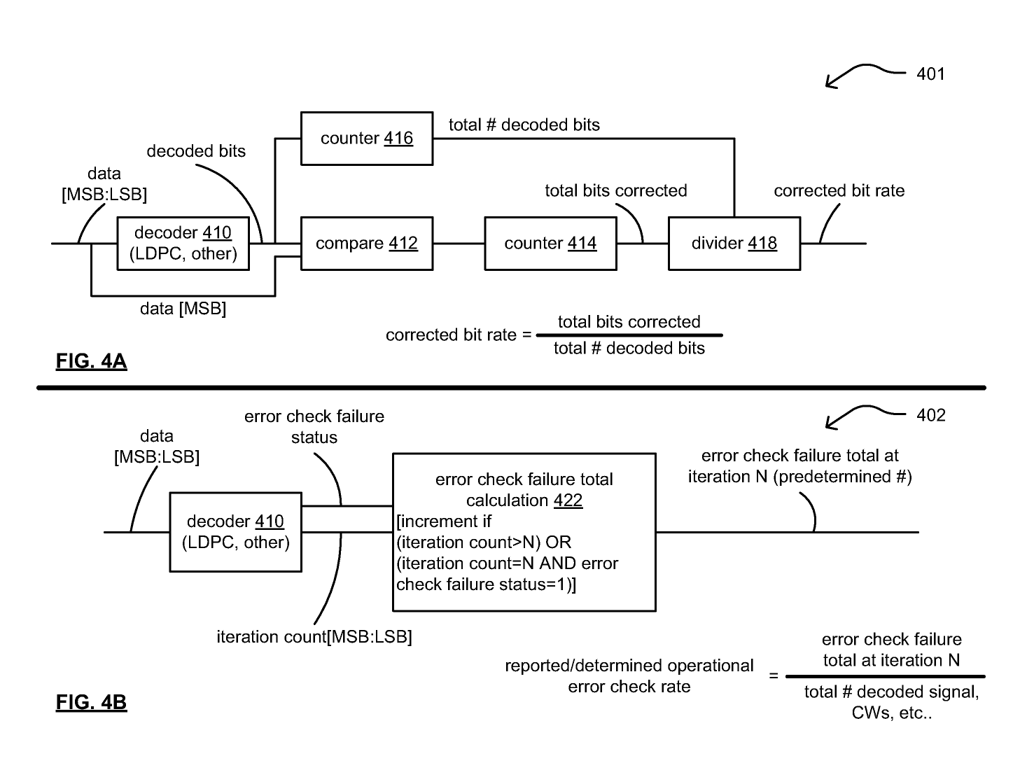

FIG. 4A is a diagram illustrating an example 401 of operations for determining SNR margin of a communication device based on decoder corrected bit rate. A decoder 410, which may be implemented as any desired type of decoder, such as LDPC, or other type of decoder, receives coded information or data and generates decoded bits therefrom. A first compare operation 412 compares the received data to the decoded bits, and a counter 414 determines how many of the total bits within the received data have been corrected during decoding as performed by the decoder 410. Also, a counter 416 determines how many total bits have been decoded by decoder 410. A divider 418 determines the ratio of the total bits corrected as output from counter 414 to the total number of decoded bits output from counter 416 to determine the corrected bit rate. A device that performs the operations of this diagram may be used to generate a decoder corrected bit rate curve for use in determining SNR margin.

FIG. 4B is a diagram illustrating an example 402 of operations for determining SNR margin of a communication device based on error check failure after performing a predetermined number of decoding iterations. In this diagram, decoder 410 receives coded signals or data and performs iterative decoding thereon to make estimates of information encoded therein. The operations within the block 422 generate the error check failure total. These operations determine an error check failure total at a predetermined number of iterations, N, that can be fewer than a maximum number of decoder iterations performed by decoder 410. For example, the error check failure status is determined at the predetermined number of iterations, N, when decoding each of the signals. After decoding a certain number of signals, the device then determines an error check failure total based on error check failure of at least one of the plurality of FEC coded signals after performing the predetermined number of decoding iterations, N. The device then applies the error check failure total relative to the number of FEC coded signals decoded to generate the operational error check rate. For example, the device divides the error check failure total by the number of FEC coded signals decoded to generate the operational error check rate. The device then applies the operational error check rate to a characterization of the communication device that relates error check rate and SNR to determine the SNR margin.

Note that a device may be implemented to use any number of different types of FEC code and/or ECC and to generate decoding statistics based thereon. For the assistance of the reader, one type of code, LDPC code, is described in further detail below. However, note that any other desired type of FEC code and/or ECC and decoding statistics associated therewith may be used to determine SNR margin.

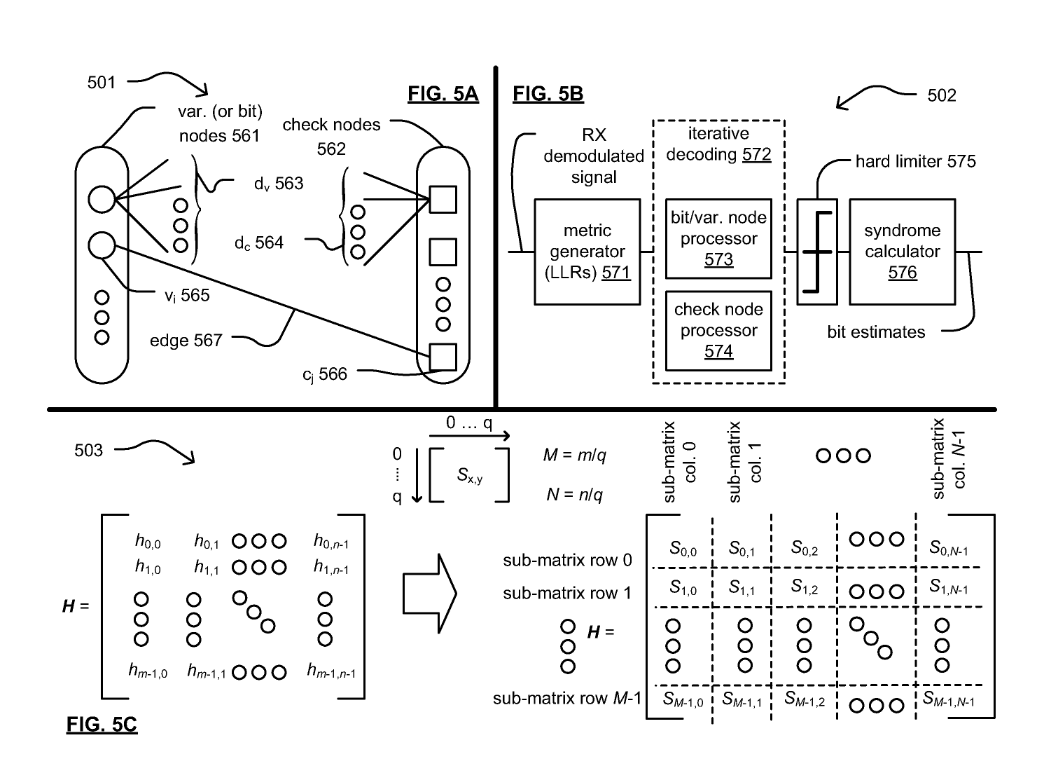

FIG. 5A illustrates an example 501 of an LDPC (Low Density Parity Check) code bipartite graph. An LDPC bipartite graph is sometimes referred to as a “Tanner” graph. An LDPC bipartite graph is a pictorial representation of an LDPC matrix of a corresponding LDPC code, and it shows the relationship of non-null elements of the LDPC matrix that performs bit or variable edge message updating (based on columns of the LDPC matrix) and check message updating (based on rows of the LDPC matrix). An LDPC code is characterized by a binary parity check matrix (i.e., LDPC matrix) that is sparse, such that nearly all of the elements of the matrix have values of zero (“0”). For example, H=(h_{i,j})_{M×N} is a parity check matrix of an LDPC code with block length N. The LDPC bipartite graph, or “Tanner” graph, is a pictorial illustration of an LDPC matrix.

LDPC codes are linear block codes and hence the set of all codewords xεC spans the null space of a parity check matrix, H, as follows:

Hx^{T}=0, ∀xεC (1)

For an LDPC code, the matrix, H, is a sparse binary matrix of dimension m×n. Each row of H corresponds to a parity check and a set element hᵢⱼ indicates that data symbol j used for the parity check i. Each column of H corresponds to a codeword symbol.

For each codeword x, there are n symbols of which m are parity symbols. Hence the code rate of the LDPC code, r, is provided as follows:

r=(n−m)/n (2)

The row and column weights are defined as the number of set elements in a given row or column of H, respectively. The set elements of H are chosen to satisfy the performance requirements of the code. The number of 1's in the i-th column of the parity check matrix, H, may be denoted as dᵥ(i), and the number of 1's in the j-th row of the parity check matrix may be denoted as d_{c}(j). If dᵥ(i)=dᵥ for all i, and d_{c}(j)=d_{c} for all j, then the LDPC code is called a (dᵥ,d_{c}) regular LDPC code, otherwise the LDPC code is called an irregular LDPC code.

A regular LDPC code can be represented as a bipartite graph by its parity check matrix with left side nodes representing variables of the coded bits (or alternatively as the “variable nodes” (or “bit nodes”) 561 in a bit-based decoding of LDPC coded signals), and the right side nodes representing check equations (or alternatively as the “check nodes” 562). The bipartite graph (or Tanner graph) of the LDPC code defined by H may be defined by N variable nodes (e.g., N bit nodes) and M check nodes. Every variable node of the N variable nodes 561 has exactly dᵥ(i) edges. As an example, edge 567 connects the bit node, vᵢ 565, to one or more of the check nodes (within the M check nodes). The edge 567 is specifically shown as connecting from the bit node, vᵢ 565, to the check node, cⱼ 566. This number of dᵥ edges (shown as 563) may be referred to as the degree of a variable node i. Analogously, a check node of the M check nodes 562 has d_{c}(j) edges (shown as d_{c} 564) connecting this node to one or more of the variable nodes (or bit nodes) 561. This number of edges, d_{c} 564, may be referred to as the degree of the check node j.

An edge 567 between a variable node vᵢ (or bit node b) 565 and check node cⱼ 566 can be defined by e=(i,j). Alternatively, given an edge e=(i, j), the nodes of the edge may alternatively be denoted as by e=(v(e),c(e)) (or e=(b(e),c(e))). The edges in the graph correspond to the set elements of H where a set element hⱼᵢ indicates that an edge connects a bit (e.g., variable) node i with parity check node j.

Given a variable node vᵢ (or bit node bᵢ), one may define the set of edges emitting from the node vᵢ (or bit node bᵢ) by Eᵥ(i)={e|v(e)=i} (or by E_{b} (i)={e|b(e)=i}); these edges are referred to as bit edges, and the messages corresponding to these bit edges are referred to as bit edge messages.

Given a check node cⱼ, one may define the set of edges emitting from the node cⱼ by E_{c}(j)={e|c(e)=j}; these edges are referred to as check edges, and the messages corresponding to these check edges are referred to as check edge messages. Continuing on, the derivative result will be |Eᵥ(i)|=dᵥ (or |E_{b}(i)|=d_{b}) and |E_{c}(j)|=d_{c}.

Generally speaking, any such codes (e.g., LDPC codes) that can be represented by a bipartite graph may be characterized as a graph code. It is also noted that an irregular LDPC code may also be described using a bipartite graph. However, the degree of each set of nodes within an irregular LDPC code may be chosen according to some distribution. Therefore, for two different variable nodes, vᵢ_{₁} and vᵢ_{₂}, of an irregular LDPC code, |Eᵥ(i₁)| may not be equal to |Eᵥ(i₂)|. This relationship may also hold true for more than one (e.g., two) check nodes.

Note that terminology such as that of “bit node” and “bit edge message”, or equivalents thereof, may be used in the art of LDPC decoding. With respect to LDPC decoding, note that “bit node” and “bit edge message” are alternatively referred to as “variable node” and “variable edge message”, respectively. Note that LDPC decoding operates to make one or more estimates of the bit values (or variable values) encoded within an LDPC coded signal.

FIG. 5B illustrates an example 502 of decoding of an LDPC coded signal. Within a communication device (e.g., communication device 110), a signal received from a communication channel undergoes appropriate demodulation (e.g., processing within an analog front end including digital sampling, digital to analog conversion, filtering, frequency conversion (up or down), gain adjustment and/or scaling, etc.) to generate a received bit sequence. Then, a metric generator 571 calculates log-likelihood ratios (LLRs) for each bit location within the received bit sequence. These LLRs correspond initially to the bit nodes 561 of the LDPC code and its corresponding LDPC bipartite graph that represents the LDPC matrix used to decode the signal.

In an example of LDPC decoding, during initialization, the LLRs are employed for the bit edge messages (e.g., extrinsic information) of the edges extending from the respective bit/variable nodes. Thereafter, one or more decoding cycles or iterations may be performed based on check node processing and bit node processing (iterative decoding 572). Check node processing or check node updating is performed using the original bit edge messages (e.g., the calculated LLRs) such as by a check node processor 574. A bit/variable node processor 573 then uses these updated check edge messages to perform bit node processing or bit node updating to update the variable node soft information for use in the next decoding iteration. The most recently updated variable bit/node soft information is then used to calculate the variable node edge messages (extrinsic information) for this next decoding iteration. The check node processor 574 performs check message updating (based on rows of the LDPC matrix) to generate updated check edge messages, and the bit/variable node processor 573 performs bit or variable edge message updating (based on columns of the LDPC matrix) as also described with reference to FIG. 5A.

When more than one decoding iteration is performed, these variable node edge messages are then used by the check node processor 574 for subsequent check node processing or check node updating to calculate updated check edge messages. Then, bit/variable node processor 573 uses the most recently updated check edge messages to perform bit node processing or bit node updating to update the variable node soft information once again. After a final decoding iteration, which may be determined based on some parameter (e.g., a predetermined number of decoding iterations or when all syndromes of the LDPC code equal zero, as determined by syndrome calculator 576), the last calculated variable node soft information may undergo hard limiting (e.g., in a slicer or hard limiter 575) to generate one or more estimates of one or more bits encoded within the LDPC coded signal.

Generally speaking, this approach for decoding of LDPC coded signals may be referred to as a message passing approach (or iterative message passing approach). Note that LDPC decoding may be performed in any of a variety of architectures including parallel decoding architectures, layer decoding architectures, etc. Device 110 may be implemented to perform encoding and/or decoding of LDPC coded signal using any desired approach or architecture.

Note that the various functional blocks and components depicted in FIG. 5B may be implemented or performed by the processor 230 (and memory 240) of communication device 110. For example, the processor 230 can be implemented to perform such decoding operations and the memory 240 can be implemented to store and perform memory management for the various bit/variable and check edge messages, variable bit/node soft information, extrinsic information, etc. used in the decoding operations.

In another example of operation, the processor 230 operates to modify a first LDPC matrix to generate a second LDPC matrix for use to decode an LDPC coded signal that is generated based on puncturing of one or more parity bits from another LDPC coded signal.

FIG. 5C illustrates an example 503 of an LDPC matrix that is partitioned into sub-matrices. This diagram shows the relationship between an overall LDPC matrix and the individual sub-matrices therein that can be all-zero-valued sub-matrices and/or CSI (Cyclic Shifted Identity) sub-matrices, and the diagram shows the sub-matrix rows and sub-matrix columns of the LDPC matrix that correspond to the sub-matrix arrangement of the LDPC matrix. Note also that a generator matrix, corresponding to an LDPC matrix, may be employed to encode at least one information bit to generate a plurality of LDPC coded bits and/or an LDPC codeword (e.g., such as using back-substitution described below). A generator matrix, G, of an LDPC code has the following relationship with LDPC matrix, H: GH^{T}=0. An LDPC code may be defined or characterized by its LDPC matrix, H, and/or its generator matrix, G.

A processor of a communication device (e.g., processor 230 of communication device 110) may be configured to encode at least one information bit to generate the plurality of LDPC coded bits and/or an LDPC codeword. The processor then transmits the plurality of LDPC coded bits and/or the LDPC codeword, within an LDPC coded signal via a communication interface (e.g., communication interface 320 of communication device 110). The processor may be configured to generate the LDPC coded signal by appropriate modulation of the plurality of LDPC coded bits and/or the LDPC codeword (e.g., processing within an analog front end including digital to analog conversion, filtering, frequency conversion (up or down), gain adjustment, etc.).

A binary LDPC code may be fully described by its parity check matrix (i.e., its LDPC matrix). At the top of the diagram, the individual elements of an LDPC matrix, H, are shown:

$$H = [ \begin{matrix}{h}_{0 , 0} & {h}_{0 , 1} & … & {h}_{0 , n - 1} \\ {h}_{1 , 0} & {h}_{1 , 1} & … & {h}_{1 , n - 1} \\ … & … & … & … \\ {h}_{m - 1 , 0} & {h}_{m - 1 , 1} & … & {h}_{m - 1 , n - 1}\end{matrix} ]$$

where n is the number of bits in a codeword, m is the number of parity check equations of the LDPC code, and h_{i,j} is either 0 or 1. An n-bit vector c (e.g., c=(c₁, c₂, . . . , c_{N})) is a codeword (i.e., of the LDPC code) if and only if Hc^{T}=0.

For such an LDPC code, the parity matrix H is also composed of a number of q-by-q (i.e., q×q) square sub-matrices as shown in the bottom portion of the diagram and also below:

$$H = [ \begin{matrix}{S}_{0 , 0} & {S}_{0 , 1} & … & {S}_{0 , N - 1} \\ {S}_{1 , 0} & {S}_{1 , 1} & … & {S}_{1 , N - 1} \\ … & … & … & … \\ {S}_{M - 1 , 0} & {S}_{M - 1 , 1} & … & {S}_{M - 1 , N - 1}\end{matrix} ]$$

where M=m/q, N=n/q, and each sub-matrix, S_{I,J}, thereof is a q-by-q sub-matrix that is either an all-zero-valued sub-matrix (i.e., in which all elements thereof are the value of zero “0”, which is depicted by a blank or an empty sub-matrix or a sub-matrix with value of “−1” therein in the associated diagrams) or a CSI (Cyclic Shifted Identity) sub-matrix. A CSI sub-matrix S is characterized by a shift-value, λ(S), (e.g., a right shift value) such that the components of S are defined as follows:

$${s}_{i , j} = \{ \begin{matrix}1 & if i + λ ( S ) = j ( mod q ) \\ 0 & otherwise\end{matrix}$$

for any i and j, with 0≦i<q and 0≦j<q. For example, the q-by-q identity matrix is itself a CSI matrix with a shift-value λ(S)=0 (i.e., a CSI sub-matrix with a cyclic shift of zero “0”).

As can be seen, the LDPC matrix (as depicted in the lower portion of the diagram), includes various sub-matrix rows and sub-matrix columns. These sub-matrix rows and columns are based on the sub-matrix construction of the LDPC matrix (e.g., shown as sub-matrix rows 0 through M−1 and sub-matrix columns 0 through N−1). This disclosure presents various new designs of LDPC codes.

Note also the following with respect to such LDPC code matrix constructions. A given LDPC code may be a QC (quasi-cyclic)-LDPC code. The definition of such an (n, k) QC-LDPC code is provided as follows:

1. (n-k)-by-n parity check matrix H

2. H is expanded from a binary base matrix H_{b} of size v-by-u

3. The base matrix H_{b} is expanded by replacing each sub-matrix in the base matrix with a size z permutation matrix, and each a blank or “−1” negative with a size z zero matrix. The permutations used are circular right shifts as described above, and the set of permutation sub-matrices contains the size z identity matrix and circular right shifted versions of the identity matrix (i.e., CSI sub-matrices).

Because each permutation matrix is specified by a single circular right shift, the binary base matrix information and permutation replacement information can be combined into a single compact model matrix H_{bm}. The model matrix H_{bm} is the same size as the binary base matrix H_{b}, with each binary entry (i,j) of the base matrix H_{b} replaced to create the model matrix H_{bm}. Each 0 in H_{b} is replaced by a blank or “−1” negative to denote a size z all-zero matrix, and each other sub-matrix in H_{b} is replaced by a circular shift size p(i,j)≧0 (e.g., an entry of “−1” indicates an all-zero-valued sub-matrix, and any other entry such as 0, 1, 2, etc. indicates an identity sub-matrix (if entry is 0), a CSI sub-matrix based on a shift-value of 1 (if entry is 1), a CSI sub-matrix based on a shift-value of 2 (if entry is 2), etc. and so on for any desired cyclic shift-value). The model matrix H_{bm} can then be directly expanded to the entire LDPC matrix, H.

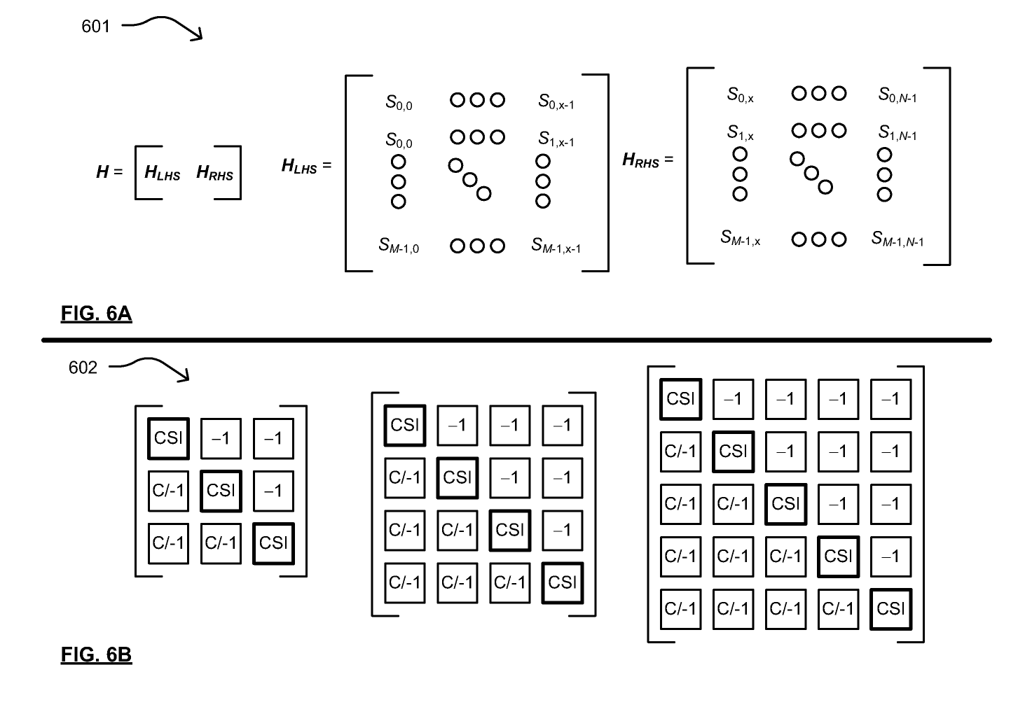

FIG. 6A is a diagram illustrating an example 601 of an LDPC matrix partitioned into a left hand side matrix and a right hand side matrix. The parity matrix H of the bottom of FIG. 5C may be partitioned into a left hand side matrix, H_{LHS}, and a right hand side (RHS) matrix, H_{RHS}. The partitioning will be in between two sub-matrix columns. This diagram shows the partitioning being between sub-matrix column x−1 and sub-matrix column x. Left hand side matrix, H_{LHS}, and RHS matrix, H_{RHS}, include the same number of sub-matrix rows. In one implementation, the RHS matrix, H_{RHS}, is a square matrix that includes a same number of sub-matrix rows and sub-matrix columns (e.g., the RHS matrix, H_{RHS}, may generally be of any size such as z-by-z, where z is any desired number such as 2, 3, 4, 5, 6, 7, or even higher numbers etc.).

FIG. 6B is a diagram illustrating examples 602 of right hand side matrices of LDPC matrices. A RHS matrix, H_{RHS}, having this form is lower triangular and includes all-zero-valued sub-matrices except for CSI (Cyclic Shifted Identity) sub-matrices located on a main diagonal of the RHS matrix and certain one or more sub-matrices located below and to the left of the main diagonal of the RHS matrix. The RHS matrix is lower triangular and includes first all-zero-valued sub-matrices located above and to the right of the main diagonal of the RHS matrix. First CSI (Cyclic Shifted Identity) sub-matrices are located on the main diagonal of the RHS matrix, and second CSI sub-matrices and/or second all-zero-valued sub-matrices are located below and to the left of the main diagonal of the RHS matrix. Those sub-matrices located below and to the left of the main diagonal of the RHS matrix are depicted in the diagram as “C/−1” since each of them may be either a CSI sub-matrix or an all-zero-valued sub-matrix.

Note also that such CSI sub-matrices may be based on different CSI values. A CSI value of zero indicates an identity sub-matrix. A CSI value of 1 indicates an identity sub-matrix that has undergone a cyclic shift by 1. Any desired CSI value may be employed up to the sub-matrix size, z, if considering sub-matrices of size z-by-z. Generally speaking, a CSI value of x indicates an identity sub-matrix that has undergone a cyclic shift by x.

While examples have been provided showing LDPC decoding, processor 230 can also be configured to perform encoding of bit(s) to generate LDPC coded bit(s) and/or LDPC codeword(s). Such encoding may be performed using back-substitution. An LDPC matrix may be partitioned into a left hand side matrix, H_{LHS,} and a right hand side matrix, H_{RHS}, such as shown in FIG. 3A. The right hand side matrix, H_{RHS}, can have the form of any of the right hand side matrices of FIG. 3B, and may be of any desired size such as 3-by-3, 4-by-4, 5-by-5, or generally of any size such as z-by-z, where z is any desired number such as 2, 3, 4, 5, 6, 7, etc.

Considering a right hand side matrix, H_{RHS,} having the form of those in FIG. 3B, a CSI sub-matrix may be a respective identity matrix that has either not been cyclic shifted (and remains an identity matrix) or a respective identity matrix that has been cyclic shifted by some amount as described above. For sub-matrices of size, L-by-L, input (information) bits, cᵢₙ (k bits=L(n−m) bits), may be represented as follows: cᵢₙ=(c₀, c₁, . . . , cₖ₋₁)

The processor 230 then encodes the input (information) bits and computes L·m parity bits, cₚₐᵣ (e.g., LDPC coded bits) as follows: cₚₐᵣ=(cₖ, cₖ₊₁, . . . , c_{Ln-1})

The processor 230 then outputs the following:

$${c}_{P}^{T} = ( \begin{matrix}{C}_{0} \\ {C}_{1} \\ {C}_{2} \\ {C}_{3} \\ {C}_{4}\end{matrix} ) , \\ where$$

$${C}_{i} = {( {c}_{L ( n - m + i )} , {c}_{L ( n - m + i ) + 1} , … , {c}_{L ( n - m + i ) + L - 1} )}^{T} .$$

For a right hand side matrix, H_{RHS}, in the form of those in FIG. 3B being of size 5-by-5 (e.g., where i varies from 0 to 4 in order of 0, 1, 2, 3, 4).

The encoding procedure may be described as follows:

Input: c₁=(c₀, c₁, . . . , cₖ₋₁)

Step 1: compute Vᵢ=H_{I,i}c_{I}^{T}, such that i=0, . . . , 4.

Step 2: back-substitution

C₀=V₀(L−u_{0,0})

C₁=V₁(L−u_{1,1})+C₀((L−u_{1,1}+u_{1,0})mOd L)

C₂=V₂(L−u_{2,2})+C₁((L−u_{2,2}+u_{2,1})mOd L)

C₃=V₃(L−u_{3,3})+C₂((L−u_{3,3}+u_{3,2})mOd L)

C₄=V₄(L−u_{4,4})+C₃((L−u_{4,4}+u_{4,3})mOd L)

$$Output \text{:} {c}_{P}^{T} = ( \begin{matrix}{C}_{0} \\ {C}_{1} \\ {C}_{2} \\ {C}_{3} \\ {C}_{4}\end{matrix} )$$

Note that this approach shows just one possible example by which encoding based on an LDPC code may be performed. Generally, the decoding operations described herein may be performed on an LDPC coded signal that is generated using any LDPC encoding approach.

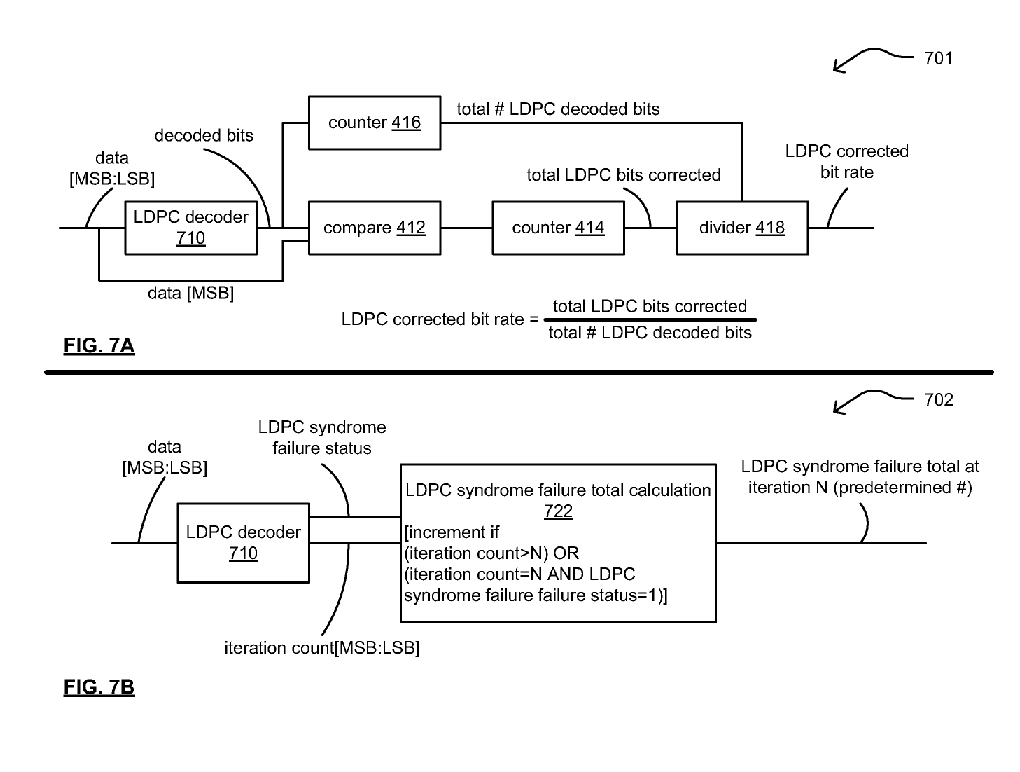

FIG. 7A is a diagram illustrating an example 701 of operations for determining SNR margin of a communication device based on LDPC decoder corrected bit rate. This diagram has some similarities to FIG. 4A with at least one difference being that this diagram deal specifically with LDPC decoding. LDPC decoder 710 receives LDPC coded information or data and generates LDPC decoded bits therefrom. A first compare operation 412 compares the received data to the LDPC decoded bits, and a counter 414 determines how many of the total bits within the received LDPC data have been corrected during decoding as performed by the decoder LDPC 710. Also, a counter 416 determines how many total bits have been decoded by LDPC decoder 710. A divider 418 determines the ratio of the total bits corrected as output from counter 414 to the total number of decoded bits output from counter 416 to determine the corrected bit rate. The device that performs the operations of this diagram may be used to generate an LDPC decoder corrected bit rate curve for use in determining SNR margin.

FIG. 7B is a diagram illustrating an example 702 of operations for determining SNR margin of a communication device based on LDPC syndrome error failure after performing a predetermined number of decoding iterations. This diagram has some similarities to FIG. 4B with at least one difference being that this diagram deal specifically with LDPC decoding as performed by LDPC decoder 710, and as such, LDPC symbol failure total calculation 722 is performed based on LDPC syndrome failure status at a predetermined number of decoding iterations that is less than the maximum number of decoding iterations performed.

In this diagram, LDPC decoder 710 receives coded signals or data and performs iterative decoding thereon to make estimates of information encoded therein. The operations within the block 722 generate an LDPC syndrome failure total. These operations determine an LDPC syndrome failure total at a predetermined number of iterations, N, that is fewer than a maximum number of LDPC decoder iterations performed by LDPC decoder 710. For example, the error check failure status is determined at the predetermined number of iterations, N, when decoding each of the signals. After decoding a certain number of signals, the device determines the LDPC syndrome failure total based on LDPC syndrome failure status of at least one of the plurality of LDPC coded signals after performing the predetermined number of decoding iterations, N. The LDPC syndrome failure rate is the ratio of the LDPC syndrome failure total to the total number of LDPC codewords decoded (e.g., the LDPC syndrome failure total divided by the total number of LDPC codewords decoded). The device applies the LDPC syndrome failure total to a number of the LDPC coded signals to a characterization of the communication device that relates error check rate and SNR.

From another perspective, the LDPC decoder 710 iteratively decodes LDPC coded signals to make estimates of information encoded therein. The block 722 determines a syndrome failure total based on syndrome failure of at least one of the plurality of LDPC coded signal after performing a predetermined number of iterations, N, that can be fewer than a maximum number of LDPC decoder iterations performed by LDPC decoder 710. The device then applies the syndrome failure total relative to the number of LDPC coded signals decoded to generate the operational error check rate. For example, the device divides the syndrome failure total by the number of LDPC coded signals decoded to generate the operational error check rate. The device then determines the SNR margin of the communication device by applying the operational error check rate to a characterization of the communication device that relates syndrome error rate and SNR.

This implementation of FIG. 7B has relatively simplest complexity among the various approaches presented herein, in that, an LDPC decoder provides the syndrome failed status indicated at the end of every iteration, so this information can be readily used to determine the SNR margin. Note also that a mapping may be made to a standardized curve would resolve the issues of different LDPC decoders that operate using different parameters (e.g., such as with respect to FIG. 10, such as in instances where different devices may use different maximum number of iterations for LDPC decoding). Note also that the value of the decoding iteration count, N, can be programmable (e.g., between 0 and 15) to provide flexibility in the SNR dynamic range and granularity.

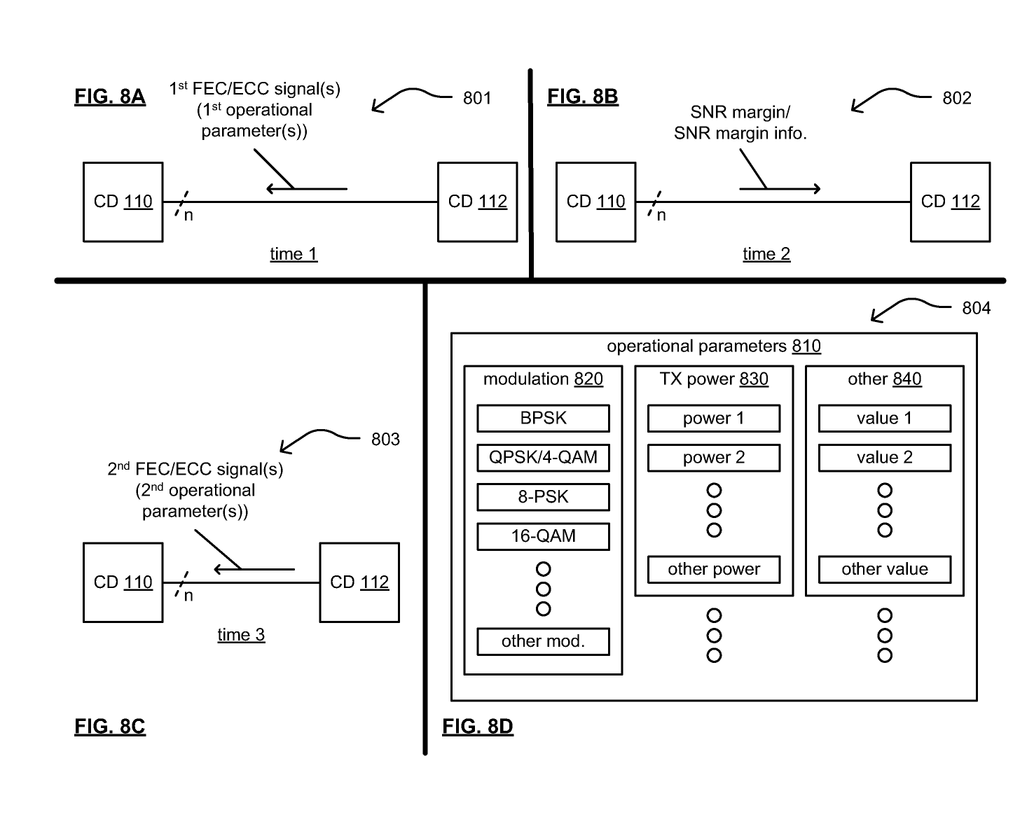

FIG. 8A is a diagram illustrating an example 801 of a communication device that receives first at least one signal from another communication device at a first time. In this diagram, the device 110 receives the first at least one signal from the device 112. The first at least one signal is based on a first at least one operational parameter. Examples of operational parameters may include transit power, modulation (constellation shape and mapping of constellation points therein), coding type, code rate, channel assignment, sub-carrier assignment such as with respect to an orthogonal frequency division multiplexing (OFDM) and/or orthogonal frequency division multiple access (OFDMA) implementation, etc.

FIG. 8B is a diagram illustrating an example 802 of the communication device of FIG. 8A that transmits SNR margin to the other communication device at a second time. The device 110 determines the SNR margin based on the first at least one signal that is received from device 112. The device 110 may use any one or more of the various approaches to determine SNR margin as described herein. Then, device 100 and transmits the SNR margin information to device 112. Alternatively, device 110 can send the determined information such as LDPC corrected bit rate and/or LDPC syndrome failure rate to device 112 so that device 112 can determine the SNR margin. For example, the device 110 need not specifically determine the SNR margin itself but can provide appropriate information to device 112 so that device 112 determines the SNR margin itself.

FIG. 8C is a diagram illustrating an example 803 of a communication device that receives second at least one signal from another communication device at a third time. In this diagram, device 110 receives the second at least one signal from device 112. The second at least one signal is based on a second at least one operational parameter. The second at least one operational parameter differs from the first at least one operational parameter by at least one value of a common operational parameter and/or may include at least one different operational parameter. In one example of operation, the second at least one signal may be received after being transmitted by the device 112 using a different power than was used to transmit the first at least one signal. In another example operation, the second least one signal may be received after being transmitted by the device 112 using a different modulation (e.g., a different modulation having a different number of constellation points thereby having a different modulation density and/or a different mapping of constellation points within a given constellation shape) than was used to transmit the first at least one signal. The device 110 communicates the SNR margin information to device 112 and FIG. 8B so that device 112 may adapt its operation or transmission of signals to device 110.

FIG. 8D is a diagram illustrating an example 804 of various operational parameters for use in generating and transmitting signals based on SNR margin and changes thereof. Examples of operational parameters 810 may include modulation 820, transit power 830, and/or any other operational parameter 840.

With respect to modulation 820, information may be modulated to generate discrete-valued modulation symbols using various modulation coding techniques. Examples of such modulation coding techniques may include binary phase shift keying (BPSK), quadrature phase shift keying (QPSK) or quadrature amplitude modulation (QAM), 8-phase shift keying (PSK), 16 quadrature amplitude modulation (QAM), 32 amplitude and phase shift keying (APSK), 64-QAM, etc., uncoded modulation, and/or any other desired types of modulation including higher ordered modulations that may include even greater number of constellation points (e.g., 1024 QAM, etc.). Generally, data within a packet may be modulated using a relatively higher-ordered modulation/modulation coding sets (MCSs) than is used for modulating SIG information. Relatively lower-ordered modulation/MCS may be used for the SIG information to ensure reception by a recipient device (e.g., being relatively more robust, easier to demodulate, decode, etc.). In an example of operation, when there is an adequate SNR margin, a transmitting device may increase the modulation density used to transmit subsequent signals (e.g., adjust from 16 QAM up to 64 QAM).

With respect to transmit power 830, a device may be implemented to transmit signals using any one of a number of different transmit powers. SNR margin of communications between two devices is determined to be relatively large, a transmitting device may adjust down transmit power to a relatively lower power to operate with a relatively smaller SNR margin. Generally speaking, the value of any operational parameter may be adjusted based on information related to SNR margin.

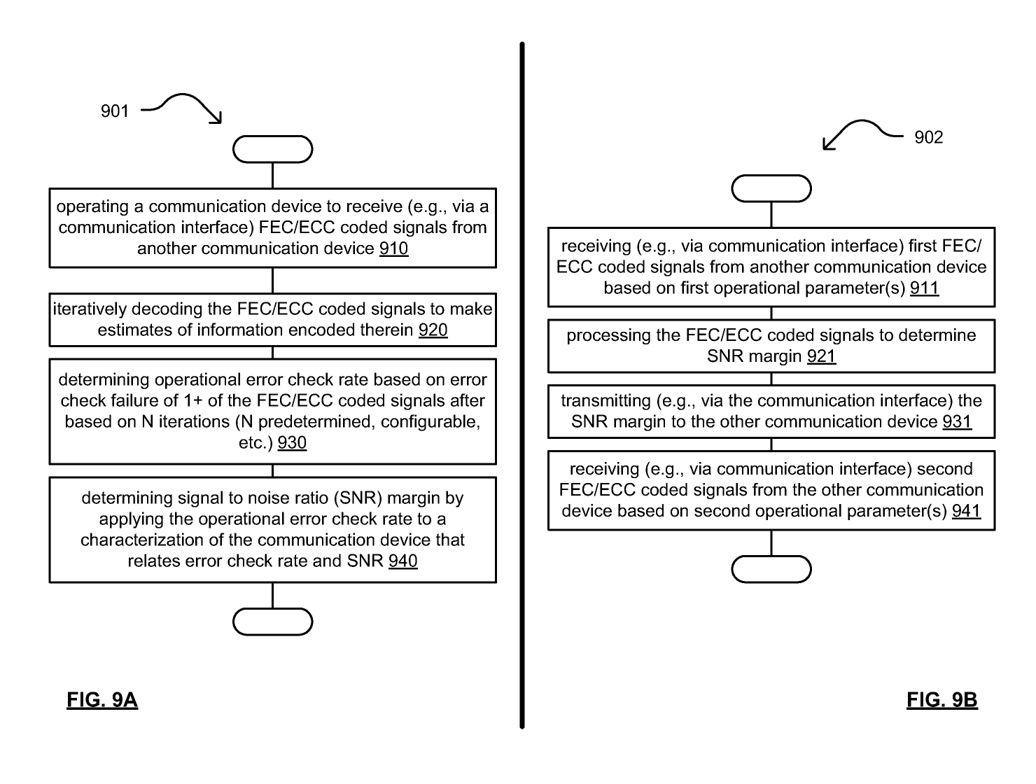

FIG. 9A is a diagram illustrating an embodiment of a method 901 for execution by one or more communication devices. The method 901 begins by receiving, via a communication interface of a communication device, a plurality of forward error correction (FEC) coded signals from another communication device (block 910). The method 901 continues by iteratively decoding the plurality of FEC coded signals to make estimates of information encoded therein (block 920).

The method 901 then operates by determining an operational error check rate based on error check failure of at least one of the plurality of FEC coded signals after performing a number of decoding iterations, N (block 930). The operational error check rate is a measure of an error check failure total relative to the number of FEC coded signals that have been decoded (e.g., the error check failure total divided by the number of FEC coded signals that have been decoded). Note that the number of decoding iterations, N, may be predetermined, configurable, etc. note that this number of decoding iterations is less than the maximum number of decoding iterations to be performed within the method 901. The method 901 continues by determining a signal to noise ratio (SNR) margin of the communication device by applying the operational error check rate to a characterization of the communication device that relates error check rate and SNR (block 940).

FIG. 9B is a diagram illustrating another embodiment of a method 902 for execution by one or more communication devices. The method 902 begins by receiving, via a communication interface of a communication device, the plurality of FEC coded signals based on a first one or more operational parameters from the other communication device (block 911). The method 902 then processes the plurality of FEC coded signals to determine SNR margin (block 921).

The method 902 continues by transmitting, via the communication interface, the SNR margin to the other communication device for use in adjusting operation of the other communication device (block 931). The method 902 continues by receiving, via the communication interface, at least one additional FEC coded signal based on a second power that is different than the first power from the other communication device (block 941).

As may be used herein, the terms “substantially” and “approximately” provides an industry-accepted tolerance for its corresponding term and/or relativity between items. Such an industry-accepted tolerance ranges from less than one percent to fifty percent and corresponds to, but is not limited to, component values, integrated circuit process variations, temperature variations, rise and fall times, and/or thermal noise. Such relativity between items ranges from a difference of a few percent to magnitude differences. As may also be used herein, the term(s) “configured to,” “operably coupled to,” “coupled to,” and/or “coupling” includes direct coupling between items and/or indirect coupling between items via an intervening item (e.g., an item includes, but is not limited to, a component, an element, a circuit, and/or a module) where, for an example of indirect coupling, the intervening item does not modify the information of a signal but may adjust its current level, voltage level, and/or power level. As may further be used herein, inferred coupling (i.e., where one element is coupled to another element by inference) includes direct and indirect coupling between two items in the same manner as “coupled to”. As may even further be used herein, the term “configured to,” “operable to,” “coupled to,” or “operably coupled to” indicates that an item includes one or more of power connections, input(s), output(s), etc., to perform, when activated, one or more its corresponding functions and may further include inferred coupling to one or more other items. As may still further be used herein, the term “associated with,” includes direct and/or indirect coupling of separate items and/or one item being embedded within another item.

As may be used herein, the term “compares favorably” or equivalent, indicates that a comparison between two or more items, signals, etc., provides a desired relationship. For example, when the desired relationship is that signal 1 has a greater magnitude than signal 2, a favorable comparison may be achieved when the magnitude of signal 1 is greater than that of signal 2 or when the magnitude of signal 2 is less than that of signal 1.

As may also be used herein, the terms “processing module,” “processing circuit,” “processor,” and/or “processing unit” may be a single processing device or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on hard coding of the circuitry and/or operational instructions. The processing module, module, processing circuit, and/or processing unit may be, or further include, memory and/or an integrated memory element, which may be a single memory device, a plurality of memory devices, and/or embedded circuitry of another processing module, module, processing circuit, and/or processing unit. Such a memory device may be a read-only memory, random access memory, volatile memory, non-volatile memory, static memory, dynamic memory, flash memory, cache memory, and/or any device that stores digital information. Note that if the processing module, module, processing circuit, and/or processing unit includes more than one processing device, the processing devices may be centrally located (e.g., directly coupled together via a wired and/or wireless bus structure) or may be distributedly located (e.g., cloud computing via indirect coupling via a local area network and/or a wide area network). Further note that if the processing module, module, processing circuit, and/or processing unit implements one or more of its functions via a state machine, analog circuitry, digital circuitry, and/or logic circuitry, the memory and/or memory element storing the corresponding operational instructions may be embedded within, or external to, the circuitry comprising the state machine, analog circuitry, digital circuitry, and/or logic circuitry. Still further note that, the memory element may store, and the processing module, module, processing circuit, and/or processing unit executes, hard coded and/or operational instructions corresponding to at least some of the steps and/or functions illustrated in one or more of the Figures. Such a memory device or memory element can be included in an article of manufacture.

One or more embodiments of an invention have been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claims. Further, the boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality. To the extent used, the flow diagram block boundaries and sequence could have been defined otherwise and still perform the certain significant functionality. Such alternate definitions of both functional building blocks and flow diagram blocks and sequences are thus within the scope and spirit of the claimed invention. One of average skill in the art will also recognize that the functional building blocks, and other illustrative blocks, modules and components herein, can be implemented as illustrated or by discrete components, application specific integrated circuits, processors executing appropriate software and the like or any combination thereof.

The one or more embodiments are used herein to illustrate one or more aspects, one or more features, one or more concepts, and/or one or more examples of the invention. A physical embodiment of an apparatus, an article of manufacture, a machine, and/or of a process may include one or more of the aspects, features, concepts, examples, etc. described with reference to one or more of the embodiments discussed herein. Further, from figure to figure, the embodiments may incorporate the same or similarly named functions, steps, modules, etc. that may use the same or different reference numbers and, as such, the functions, steps, modules, etc. may be the same or similar functions, steps, modules, etc. or different ones.

Unless specifically stated to the contra, signals to, from, and/or between elements in a figure of any of the figures presented herein may be analog or digital, continuous time or discrete time, and single-ended or differential. For instance, if a signal path is shown as a single-ended path, it also represents a differential signal path. Similarly, if a signal path is shown as a differential path, it also represents a single-ended signal path. While one or more particular architectures are described herein, other architectures can likewise be implemented that use one or more data buses not expressly shown, direct connectivity between elements, and/or indirect coupling between other elements as recognized by one of average skill in the art.

The term “module” is used in the description of one or more of the embodiments. A module includes a processing module, a processor, a functional block, hardware, and/or memory that stores operational instructions for performing one or more functions as may be described herein. Note that, if the module is implemented via hardware, the hardware may operate independently and/or in conjunction with software and/or firmware. As also used herein, a module may contain one or more sub-modules, each of which may be one or more modules.

While particular combinations of various functions and features of the one or more embodiments have been expressly described herein, other combinations of these features and functions are likewise possible. The present disclosure of an invention is not limited by the particular examples disclosed herein and expressly incorporates these other combinations.

What is claimed is:

1. A communication device comprising:
a communication interface; and
a processor, the processor and the communication interface configured to:
receive a plurality of forward error correction (FEC) coded signals from an other communication device;
decode iteratively the plurality of FEC coded signals to make estimates of information encoded therein;
determine an operational error check rate based on error check failure of at least one of the plurality of FEC coded signals after performing a predetermined number of decoding iterations; and
determine a signal to noise ratio (SNR) margin of the communication device by applying the operational error check rate to a characterization of the communication device that relates error check rate and SNR.

2. The communication device of claim 1, wherein the processor and the communication interface are further configured to:
decode iteratively the plurality of FEC coded signals to make estimates of information encoded therein, wherein the plurality of FEC coded signals includes low density parity check (LDPC) coded signals;
determine a syndrome failure total based on syndrome failure of at least one of the plurality of LDPC coded signal after performing a predetermined number of LDPC decoding iterations; and
determine the SNR margin of the communication device by applying the syndrome failure total relative to the number of the plurality of FEC coded signals to a characterization of the communication device that relates syndrome error rate and SNR.

3. The communication device of claim 1, wherein the processor and the communication interface are further configured to:
generate preliminary hard decisions for bits within the plurality of FEC coded signals before iteratively decoding the plurality of FEC coded signals to make the estimates of the information encoded therein;
determine a total number of corrected bits based on a number of preliminary hard decisions that are changed by iteratively decoding the plurality of FEC coded signals to make the estimates of the information encoded therein;
generate a corrected bit rate based on a ratio of the total number of corrected bits and a total number of decoded bits that is decoded by iteratively decoding the plurality of FEC coded signals; and
determine the SNR margin of the communication device by applying the corrected bit rate to a characterization of the communication device that relates bit error rate (BER) or block error rate (BLER) and SNR.

4. The communication device of claim 1, wherein the processor and the communication interface are further configured to:
transmit the SNR margin to the other communication device for use in adjusting operation of the other communication device.

5. The communication device of claim 1, wherein the processor and the communication interface are further configured to:
receive the plurality of FEC coded signals transmitted based on a first power from the other communication device;
transmit the SNR margin to the other communication device for use in adjusting operation of the other communication device; and
receive at least one additional FEC coded signal transmitted based on a second power that is different than the first power from the other communication device.

6. The communication device of claim 1, wherein the processor and the communication interface are further configured to:
receive the plurality of FEC coded signals based on a first modulation density from the other communication device;
transmit the SNR margin to the other communication device for use in adjusting operation of the other communication device; and
receive at least one additional FEC coded signal based on a second density that includes more or fewer constellation points than the first modulation density from the other communication device.

7. The communication device of claim 1 further comprising:
a cable modem, wherein the other communication device is a cable headend transmitter or a cable modem termination system (CMTS).

8. The communication device of claim 1 further comprising:
the processor and the communication interface configured to support communications within at least one of a satellite communication system, a wireless communication system, a wired communication system, a fiber-optic communication system, or a mobile communication system.

9. A communication device comprising:
a communication interface; and
a processor, the processor and the communication interface configured to:
receive a plurality of forward error correction (FEC) coded signals from an other communication device;
decode iteratively the plurality of FEC coded signals to make estimates of information encoded therein;
determine an operational error check rate based on error check failure of at least one of the plurality of FEC coded signals after performing a predetermined number of decoding iterations;
determine a signal to noise ratio (SNR) margin of the communication device by applying the operational error check rate to a characterization of the communication device that relates error check rate and SNR;
transmit the SNR margin to the other communication device for use in adjusting operation of the other communication device; and
receive at least one additional FEC coded signal from the other communication device that is transmitted using at least one different operational parameter than is used to transmit the plurality of FEC coded signals.

10. The communication device of claim 9, wherein the processor and the communication interface are further configured to:
decode iteratively the plurality of FEC coded signals to make estimates of information encoded therein, wherein the plurality of FEC coded signals includes low density parity check (LDPC) coded signals;
determine a syndrome failure total based on syndrome failure of at least one of the plurality of LDPC coded signal after performing a predetermined number of LDPC decoding iterations; and
determine the SNR margin of the communication device by applying the syndrome failure total relative to a number of the plurality of FEC coded signals to a characterization of the communication device that relates syndrome error rate and SNR.

11. The communication device of claim 9, wherein the processor and the communication interface are further configured to:
generate preliminary hard decisions for bits within the plurality of FEC coded signals before iteratively decoding the plurality of FEC coded signals to make the estimates of the information encoded therein;
determine a total number of corrected bits based on a number of preliminary hard decisions that are changed by iteratively decoding the plurality of FEC coded signals to make the estimates of the information encoded therein;
generate a corrected bit rate based on a ratio of the total number of corrected bits and a total number of decoded bits that is decoded by iteratively decoding the plurality of FEC coded signals; and
determine the SNR margin of the communication device by applying the corrected bit rate to a characterization of the communication device that relates bit error rate (BER) or block error rate (BLER) and SNR.

12. The communication device of claim 9 further comprising:
a cable modem, wherein the other communication device is a cable headend transmitter or a cable modem termination system (CMTS).

13. The communication device of claim 9 further comprising:
the processor and the communication interface configured to support communications within at least one of a satellite communication system, a wireless communication system, a wired communication system, a fiber-optic communication system, or a mobile communication system.

14. A method for execution by a communication device, the method comprising:
receiving, via a communication interface of the communication device, a plurality of forward error correction (FEC) coded signals from an other communication device;
iteratively decoding the plurality of FEC coded signals to make estimates of information encoded therein;
determining an operational error check rate based on error check failure of at least one of the plurality of FEC coded signals after performing a predetermined number of decoding iterations; and
determining a signal to noise ratio (SNR) margin of the communication device by applying the operational error check rate to a characterization of the communication device that relates error check rate and SNR.

15. The method of claim 14 further comprising:
iteratively decoding the plurality of FEC coded signals to make estimates of information encoded therein, wherein the plurality of FEC coded signals includes low density parity check (LDPC) coded signals;
determining a syndrome failure total based on syndrome failure of at least one of the plurality of LDPC coded signal after performing a predetermined number of LDPC decoding iterations; and
determining the SNR margin of the communication device by applying the syndrome failure total relative to the number of the plurality of FEC coded signals to a characterization of the communication device that relates syndrome error rate and SNR.

16. The method of claim 14 further comprising:
generating preliminary hard decisions for bits within the plurality of FEC coded signals before iteratively decoding the plurality of FEC coded signals to make the estimates of the information encoded therein;
determining a total number of corrected bits based on a number of preliminary hard decisions that are changed by iteratively decoding the plurality of FEC coded signals to make the estimates of the information encoded therein;
generating a corrected bit rate based on a ratio of the total number of corrected bits and a total number of decoded bits that is decoded by iteratively decoding the plurality of FEC coded signals; and
determining the SNR margin of the communication device by applying the corrected bit rate to a characterization of the communication device that relates bit error rate (BER) or block error rate (BLER) and SNR.

17. The method of claim 14 further comprising:
receiving, via the communication interface, the plurality of FEC coded signals based on a first power from the other communication device;
transmitting, via the communication interface, the SNR margin to the other communication device for use in adjusting operation of the other communication device; and
receiving, via the communication interface, at least one additional FEC coded signal based on a second power that is different than the first power from the other communication device.

18. The method of claim 14 further comprising:
receiving, via the communication interface, the plurality of FEC coded signals based on a first modulation density from the other communication device;
transmitting, via the communication interface, the SNR margin to the other communication device for use in adjusting operation of the other communication device; and
receiving, via the communication interface, at least one additional FEC coded signal based on a second density that includes more or fewer constellation points than the first modulation density from the other communication device.

19. The method of claim 14, wherein the communication device is a cable modem, and the other communication device is a cable headend transmitter or a cable modem termination system (CMTS).

20. The method of claim 14 further comprising:
operating the communication interface of the communication device to support communications within at least one of a satellite communication system, a wireless communication system, a wired communication system, a fiber-optic communication system, or a mobile communication system.
